(19) United States
(12) Patent Application Publication
(10) Pub. No.: US 2010/0119734 A1
(43) Pub. Date: May 13, 2010

(54) LAMINAR FLOW IN A PRECURSOR SOURCE CANISTER

(75) Inventor: KENRIC T. CHOI, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/267,026

(22) Filed: Nov. 7, 2008

(51) Int. Cl. C23C 16/448; B65D 83/14; B01F 3/02

(52) U.S. Cl. 427/593; 118/715; 118/724; 427/248.1; 261/74; 222/145.5

(57) ABSTRACT

A canister apparatus for supplying a precursor material is disclosed. The canister apparatus includes a container defining an interior volume adapted to confine a precursor material, a tubular member adapted to introduce a carrier gas into the container, wherein the tubular member includes a distal end, and perforated portion spaced apart from the distal end that includes a plurality of radial holes, and an outlet adapted to flow out the precursor material and the carrier gas.

### BACKGROUND OF THE INVENTION

1. Field of the Invention

Embodiments of the present invention relate to a precursor source canister, sometimes referred to as an ampoule, for providing a vaporized precursor material to a processing chamber.

2. Description of the Related Art

Chemical vapor deposition (CVD) and atomic layer deposition (ALD) are well-known techniques for forming a layer or layers of a material on a substrate. The material is generally formed by the reaction of vapor phase chemicals on and/or near the surface of the substrate. Typically, CVD and ALD processes involve the delivery of gaseous reactants to the substrate surface where a chemical reaction takes place under temperature and pressure conditions favorable to the thermodynamics of the reaction. The type, composition, deposition rate, and thickness uniformity of the materials that may be formed using conventional CVD or ALD processes are generally limited by the ability to deliver chemical reactants or precursors to the substrate surface.

The precursor materials to form the gaseous reactants may originate from either a liquid precursor material or a solid precursor material. The liquid or solid precursor material is typically provided to a canister where the material is heated to form vapors. The vapors typically flow to a processing chamber having the substrate therein and react to deposit a material on the substrate surface.

Many conventional canisters are commercially available for delivery of precursors to the processing chamber. However, the conventional canisters create challenges. For example, turbulent flow within the canister may pick up or entrain solids or liquids in a carrier gas that flows along with the vapors to the processing chamber. The entrained solids or liquids may result in particle contamination of the processing chamber and/or the substrate.

Therefore, there is a need for an improved canister capable of minimizing or eliminating turbulence of the gas flow within the canister.

### SUMMARY OF THE INVENTION

Embodiments of the present invention generally provide a canister apparatus capable of providing a laminar flow inside the canister. In one embodiment, the canister apparatus comprises a container defining an interior volume and an inlet and an outlet in fluid communication with the interior volume, the container having an outer sidewall comprising a first diameter transitioning to an extended flange portion having a second diameter that is greater than the first diameter, and a tubular member extending through the inlet to a distal end thereof adjacent a bottom surface of the interior volume, the tubular member having an upper portion with a plurality of holes formed therethrough at an angle that is substantially normal to a longitudinal axis of the tubular member, each of the plurality of holes configured to allow introduction of a carrier gas into the interior volume.

In another embodiment, a method for providing a vaporized precursor material to a processing chamber is disclosed. The present invention method includes providing a container defining an interior volume containing a precursor material, heating the precursor material to form a vapor, flowing a carrier gas into the interior volume from a tubular member disposed in the interior volume, wherein the carrier gas is introduced from a perforated portion of the tubular member and the flow path is substantially normal relative to and parallel with the upper surface of the precursor material, and flowing the carrier gas and vapor to an outlet.

In another embodiment, a canister apparatus is disclosed. The canister apparatus includes an annular body having a first diameter coupled to an outwardly extending flange portion having a second diameter greater than the first diameter, an interior volume defined by the annular body, the interior volume comprising a first inside diameter transitioning to a second inside diameter that is greater than the first inside diameter, and a plurality of arcuate shoulder regions coupled to and extending inwardly away from the second inside diameter wherein each of the arcuate shoulder regions includes a threaded opening adapted to receive a fastener.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a cross-sectional view of one embodiment of a precursor source canister.

FIG. 1B is a top view of the precursor source canister shown in FIG. 1A without the lid.

FIG. 1C is a partial cross-sectional view of one embodiment of the upper portion of a tubular member.

FIG. 2 is a cross-sectional view of another embodiment of a precursor source canister.

FIG. 3 is a cross-sectional view of another embodiment of a precursor source canister.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to a canister, which may also be known as an ampoule, adapted to contain a precursor material. In particular, the embodiments described herein relate to a canister apparatus equipped with the perforated tubular member capable of minimizing or eliminating turbulence inside the canister, and minimizing or eliminating particle entrainment and/or particle generation.

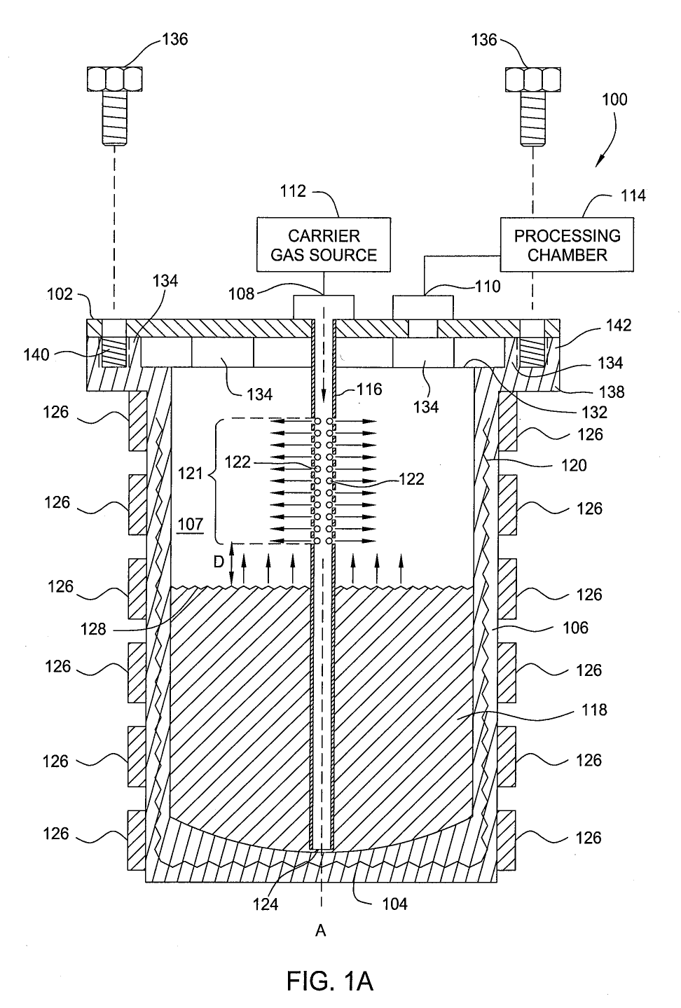

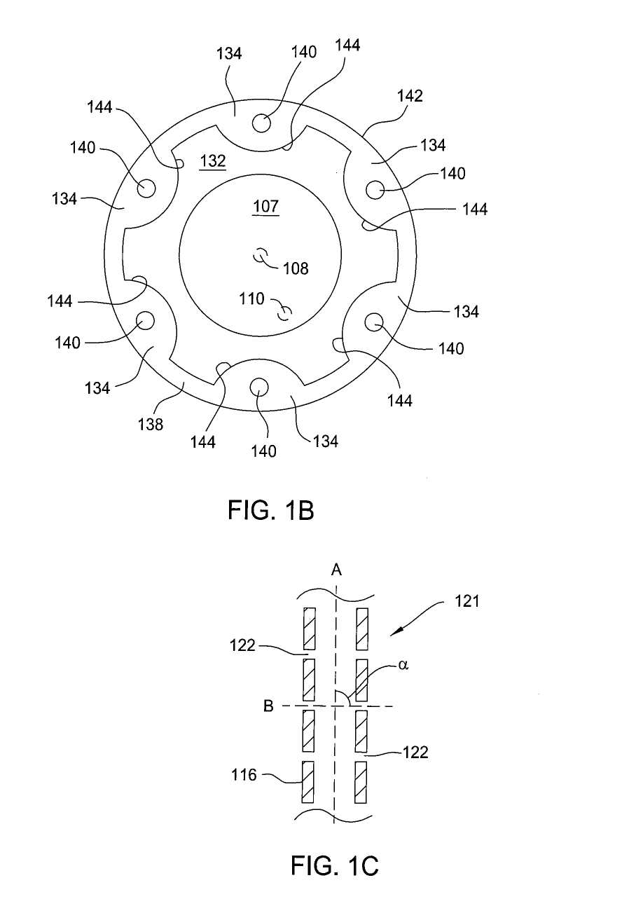

FIG. 1 illustrates one embodiment of a precursor source canister 100. The canister 100 comprises a lid 102, a bottom 104, and sidewalls 106 that define an interior volume 107. The canister 100 may be made from process resistant materials, such as stainless steel, ceramics, or aluminum. The canister 100 also comprises openings in the lid 102 configured as an inlet 108 and an outlet 110. The inlet 108 is coupled to a carrier gas source 112, and the outlet 110 is coupled to a processing chamber 114. The carrier gas source 112 supplies a carrier gas that is introduced into the interior volume 107 through a tubular member 116. The interior volume 107 of the canister 100 is adapted to contain a precursor material 118, which may be in a liquid phase or solid phase. In this embodiment, the precursor material 118 is a liquid precursor material.

Examples of suitable precursor source materials disposed in the ampoule 110 and/or delivered from remote precursor material source 180 include titanium tetrachloride (TiCl₄), tetrakis(dimethylamido)titanium (TDMAT, (Me₂N)₄Ti)), tetrakis(diethylamido)titanium (TEMAT, (Et₂N)₄Ti)), bis(ethylcyclopentadienyl)ruthenium((EtCp)₂Ru), bis(dimethylpentadienyl)ruthenium, bis(diethylpentadienyl)ruthenium, tetrakis(dimethylamido)hafnium(TDMAH, (Me₂N)₄Hf)), tetrakis(diethylamido) hafnium(TDEAH, (Et₂N)₄Hf)), tetrakis(methylethylamido)hafnium(TMEAH, (MeEtN)₄Hf)), tertbutylimido-tris(dimethylamido)tantalum(TBTDAT, (^{t}BuN)Ta(NMe₂)₃), tertbutylimido-tris(diethylamido)tantalum(TBTDET, (^{t}BuN)Ta(NEt₂)₃), tertbutylimido-tris(methylethylamido)tantalum(TBTMET, (^{t}BuN)Ta(NMe₂)₃), pentakis(dimethylamido)tantalum(PDMAT, Ta(NMe₂)₅), tertiaryamylimido-tris(dimethylamido)tantalum(TAIMATA, (^{t}AmylN)Ta(NMe₂)₃), wherein ^{t}Amyl is the tertiaryamyl group (C₅H₁₁— or CH₃CH₂C(CH₃)₂—), derivatives thereof, or combinations thereof. Other suitable exemplary precursor source materials include water, hydrogen peroxide (H₂O₂), ammonia (NH₃), hydrazine (N₂H₄). Suitable silicon precursor source materials include silane (SiH₄), disilane (Si₂H₆), chlorosilane (SiH₃Cl), dichlorosilane (SiH₂Cl₂), trichlorosilane (SiHCl₃), silicon tetrachloride (SiCl₄), hexachlorodisilane (Si₂Cl₆), and derivatives thereof.

The precursor material 118 is heated within the canister 100 to a vapor phase and the vapors are flowed to the processing chamber 114. In one embodiment, a heater element 120 may be embedded within or coupled to the sidewalls 106. In another embodiment, a heating device 126 may be coupled to, surround, or otherwise be in thermal communication with the sidewalls 106 and other surfaces of the canister 100. In one embodiment, the heating device 126 is a heated jacket or heater tape. In another embodiment, the canister 100 may be placed adjacent or in a heat source (not shown), such as an oven, a heated tube, or a hot plate. The heater element 120 or heating device 126 is operable to heat and vaporize the precursor material 118. The vaporized precursor material 118 may then be flowed out by the carrier gas through the outlet 110 to the processing chamber 114.

An upper portion 121 of the tubular member 116 is perforated and includes a plurality of radial holes 122 configured to direct flow of the carrier gas in a direction substantially normal to the longitudinal axis A of the tubular member 116 and/or the canister 100. The radial holes 122 may be distributed in a pattern or randomly on the outer peripheral surface of the tubular member 116. A portion of the introduced carrier gas may thereby flow out of the tubular member 116 through the holes 122 horizontally as shown and in a direction orthogonal and/or approximately parallel to the surface 128 of the precursor material 118. The height of the upper portion 121 containing the radial holes 122 may be set so that the radial holes 122 remain constantly above the top surface 128 of the precursor material 118. In one embodiment, a minimum distance D from the lowermost hole 122 of the upper portion 121 to the top surface 128 of the precursor material 118 is about 0.25 inches.

In one embodiment, a distal end of the tubular member 116 includes an opening 124 configured to introduce a portion of the carrier gas within the precursor material 118. In one implementation, the opening 124 may also be sealed or capped so that the carrier gas is allowed to flow only through the radial holes 122. In another embodiment, the distal end of the tubular member 116 includes a cap (not shown) having small apertures configured to restrict carrier gas flow from the distal end.

As the holes 122 are set at a minimum distance D from the top surface 128 of the precursor material 118, the carrier gas flowing out through the holes 122 do not directly impinge on the precursor material 118. Moreover, the opening 124 may have a small size so as to restrict the amount of carrier gas flowing into the precursor material 118. The configuration of the holes 122 and opening 124 may be constructed such that gas flow provided to the opening 124 is minimized and gas flow through the holes 122 above the precursor material 118 is maximized. Thus, particle generation from the precursor material 118 is mitigated or eliminated entirely by the increase in gas flow occurring above the top surface 128 of the precursor material 118. When the precursor material 118 is heated by the heater element 120, the precursor material 118 begins to vaporize. The portion of carrier gas flowing out through the radial holes 122 creates a laminar flow path, which is substantially normal to the direction in which the tubular member 116 extends and the carrier gas is adapted to flow the vapor phase precursor material to the outlet 110 in a controlled manner. This flow path provided by one or both of the holes 122 and opening 124 prevents or minimizes turbulence and particle generation.

The canister 100 further includes an annular shelf region 132 adapted to increase the volume or head space of the canister 100. In one embodiment, the annular shelf region 132 is provided by an enlarged diametrical portion of the upper portion of the canister 100. The enlarged upper portion of the canister 100 comprises an outwardly extending flange portion 138. In one embodiment, the annular shelf region 132 extends radially outward from the external portion of sidewalls 106 of the canister 100. The outwardly extending flange portion 138 is coupled to an annular sidewall 142 having a greater diameter than the outer diameter of the sidewalls 106. The annular sidewall 142 provides an upper surface adapted to couple to the lid 102. In one aspect, the annular shelf region 132 increases the head space of the interior volume 107. The lid 102 is adapted to couple to the body of the canister 100 by a plurality of fasteners 136, such as screws or bolts. The annular shelf region 132 further includes a plurality of shoulders 134 to increase the thickness of the upper portion of the canister 100 so as to provide additional mechanical support for the fasteners 136. In one embodiment, each shoulder 134 includes at least one threaded hole 140 through which a fastener 136 may be inserted. In this embodiment, the lid 102 is coupled to the canister 100 by six fasteners 136 (only three are shown in this view). In other embodiments, the lid 102 may be coupled to the canister 100 by more or less fasteners 136 adapted to be received by a corresponding number of holes 140.

In conjunction with FIG. 1A, FIG. 1B is a top view illustrating the annular shelf region 132 with the lid 102 removed. The approximate positioning of the inlet 108 and outlet 110 formed in the central portion of the lid 102 (not shown) are shown in phantom. The annular shelf region 132 includes a plurality of shoulders 134 that are configured as semicircular regions within the annular shelf region 132. In one embodiment, the shoulders 134 includes a threaded bolt hole 140 adapted to receive a fastener 136.

In one embodiment, the plurality of shoulders 134 are equally spaced on the annular shelf region 132. Each of the plurality of shoulders 134 include an arcuate portion 144 bowing inwardly toward the interior volume 107 and interfacing with arcuate portions of the interior of the annular sidewall 142. The area between the shoulders 134 and the interior of the annular sidewall 142 increases the volume of the canister 100. In one embodiment, the annular shelf region 132 defines an expanded diameter portion of the interior volume 107. The annular shelf region 132 transitions inward to the reduced diameter of the interior volume 107. In this configuration, head space of the canister is increased, which may facilitate extended dwell time of the carrier gas and vapors carried therein. Thus a greater concentration of vapors may be provided to the processing chamber.

In conjunction with FIG. 1A, FIG. 1C illustrates the placement of the radial holes 122 on the upper portion 121 of the tubular member 116. The radial holes 122 are formed through the peripheral surface of the tubular member 116 along an axis B and at an angle substantially normal to the longitudinal axis A.

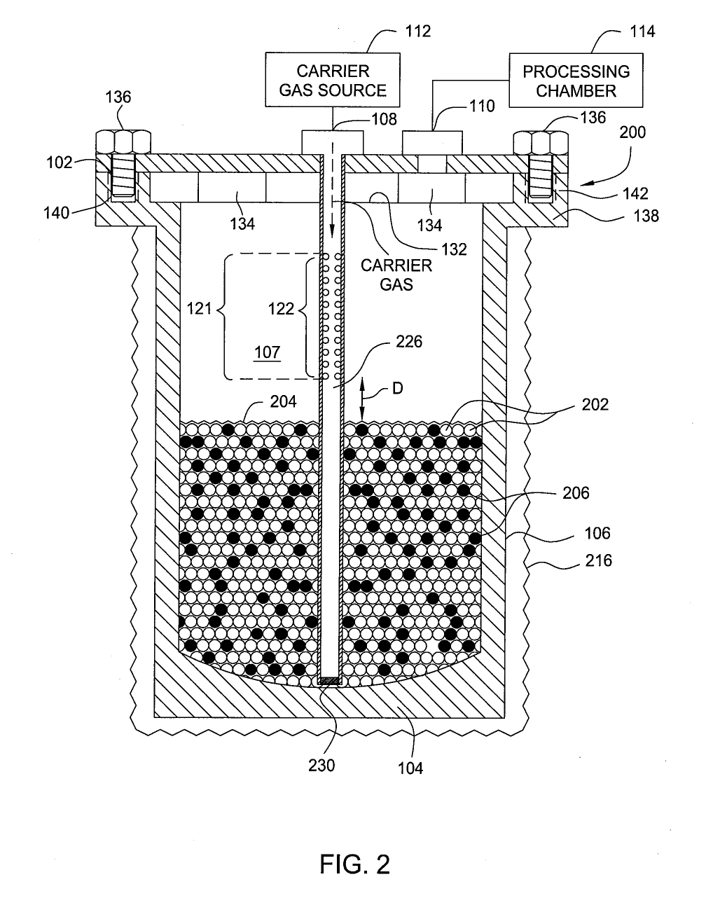

In conjunction with FIG. 1A, FIG. 2 illustrates another canister 200 according to one embodiment of the present invention. The canister 200 contains a solid phase precursor material 202. The canister 200 comprises the interior volume 107 defined by the lid 102, bottom 104, and sidewalls 106. The solid precursor material 202 may be introduced into the interior volume 107 by removing the lid 102.

In this embodiment, a heater element 216 surrounds at least a portion of the canister 200. The heater element 216 may be any heat source configured to provide thermal energy to the surfaces of the canister 200. In one embodiment, the heater element 216 is heater tape that may be in direct contact with surfaces of the canister 200. The solid precursor material 202 may be vaporized and/or sublimed when heated by the heater element 216. In one embodiment, a slurry 204 and/or solid particles 206 may be also provided within the precursor material 202 to facilitate heat transfer from the heater element 216.

The canister 200 includes the inlet 108 and outlet 110. The inlet 110 is coupled to a carrier gas source 112, and the outlet 110 is connected to a processing chamber 114. The carrier gas source 112 is adapted to provide a carrier gas into the interior volume 107 through the inlet 108 and a tubular member 226 coupled to the inlet 108.

In this embodiment, the tubular member 226 has distal end including a cap 230. The cap 230 enables higher flow of carrier gas through the plurality of radial holes 122 formed in the upper portion 121 of the tubular member 226. The cap 230 also prevents flow of carrier gas within or near the precursor material 202, which minimizes or eliminates particle contamination. The radial holes 122 are formed on the peripheral surface of the tubular member 226. The height of the upper portion 121 containing the radial holes 122 may be set so that the radial holes 122 remain constantly above the top surface of the precursor material 202. In one embodiment, a minimum distance D from the lowermost radial hole 122 to the top surface of the precursor material 202 may be about a 0.25 inches.

As the holes 122 are set at a minimum distance D from the top surface of the precursor material 202, the carrier gas flowing out through the holes 122 would not directly impinge on the precursor material 202. The cap 230 might be configured to prevent any carrier gas from being flowed out. In another implementation, the cap 230 of the tubular member 226 might be having a plurality of apertures (not shown) so that a limited amount of the carrier gas might be flowing out of the tubular member 226 through those apertures. The configuration of the radial holes 122 and apertures may be constructed such that gas flow provided to the apertures is minimized and gas flow above the precursor material 202 is maximized. Thus, particle generation from the precursor material 202 is mitigated or eliminated entirely by the increase in gas flow occurring above the precursor material 202.

When the precursor material 202 is heated by the heater element 216, the precursor material 202 begins to vaporize. The portion of carrier gas flowing out through the radial holes 122 creates a laminar flow path, which is substantially normal to the direction in which the tubular member 226 extends and the carrier gas is adapted to flow the vapor phase precursor material to the outlet 110 in a controlled manner.

The canister 200 includes the annular shelf region 132 adapted to increase the volume or head space of the canister as shown in FIG. 1A. In one embodiment, the annular shelf region 132 is provided by an enlarged diametrical portion of the upper portion of the canister 100. The enlarged upper portion of the canister 100 comprises an outwardly extending flange portion 138. The outwardly extending flange portion 138 is coupled to an annular sidewall 142 having a greater diameter than the outer diameter of the sidewalls 216. In one aspect, the annular shelf region 132 further includes a plurality of shoulders 134 to increase the thickness of the upper portion of the canister 200.

After exiting the radial holes 122, the carrier gas flows generally parallel to a top surface of the precursor material 202, and then converges toward the outlet 110. Because the flow of the carrier gas through the radial holes 122 contributes to an increase in the gas pressure above the top surface of the precursor material 202, the “stirring-up” effect of the precursor material 202 owing to the release of the carrier gas can be minimized.

Since the radial holes 122 are arranged to direct the carrier gas substantially horizontally out of the tubular member 226 and above the top surface of the precursor material 202, laminar flow paths of the carrier gas can be created to flow the vaporized precursor material 202 controllably and evenly to the outlet 110. As a result, the occurrence of turbulent flowing in the interior volume 107 can be prevented, and solid portions of the precursor material 202 are not carried away when the vaporized precursor material 202 is evacuated by the carrier gas. In one embodiment, the distal end of the tubular member 226 may extend proximate to the bottom of the interior volume 107.

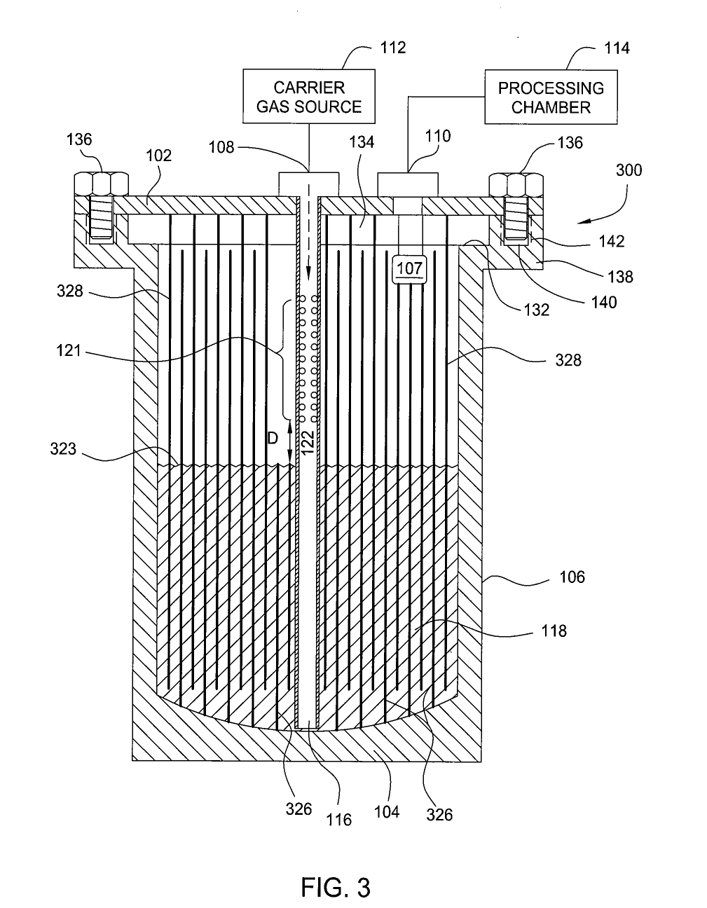

In conjunction with FIGS. 1A and 2, FIG. 3 illustrates another embodiment of a canister 300 according to one embodiment of the present invention. The canister 300 includes a plurality of baffles 326 and 328. Though the precursor material 118 is shown in liquid phase, it is understood that the precursor material 118 could also be in a solid phase such as the precursor material 202 shown in FIG. 2.

The plurality of baffles 326 and 328 may be provided in the interior volume 107 such that the baffles 326 and 328 extend substantially parallel to the tubular member 116. The baffles 326 may be coupled to the bottom 104, and the baffles 328 may be coupled to the lid 102. The baffles 326 and 328 may be made from materials resistant to the process environment of the interior volume 107, such as ceramics, stainless steel or aluminum. The baffles 326 and 328 are in contact with the precursor material 118 so as to facilitate heat transfer into the precursor material 118. In addition, the configuration of the baffles 326 and 328 may also provide a greater mean flow path of the carrier gas from the radial holes 122 toward the outlet 110 such that a higher density of vapors may be combined with the carrier gas. Thereafter, the vaporized precursor material 118 could be flowed to the processing chamber 114. The carrier gas originating from the carrier gas source 112 is introduced into the interior volume 107 by the tubular member 116.

The upper portion 121 of the tubular member 116 is perforated and includes the plurality of radial holes 122. The radial holes 122 may be distributed in a pattern or randomly on the outer peripheral surface of the tubular member 116. A portion of the introduced carrier gas may thereby flow out of the tubular member 116 through the radial holes 122 horizontally as shown and in a direction orthogonal and/or approximately parallel to the top surface 323 of the precursor material 118. The height of the upper portion 121 containing the radial holes 122 may be set so that the radial holes 122 remain constantly above the top surface 323 of the precursor material 118. In one embodiment, a minimum distance D from the lowermost redial hole 122 to the top surface 323 of the precursor material 118 is about 0.25 inches. With the baffles 326 and 328, the carrier gas flowed out of the radial holes 122 could be moving in a direction substantially parallel to those baffles 326 and 328, thus creating a laminar flow along the direction in which the baffles 326 and 328 extend.

While the foregoing is directed to embodiments of the present invention, other and further embodiments of the invention thus may be devised without departing from the basic scope thereof, and the scope thereof is determined by the claims that follow.

1. An apparatus for supplying a precursor material to a processing chamber, comprising:
a container defining an interior volume and an inlet and an outlet in fluid communication with the interior volume, the container having an outer sidewall comprising a first diameter transitioning to an extended flange portion having a second diameter that is greater than the first diameter; and
a tubular member extending through the inlet to a distal end thereof adjacent a bottom surface of the interior volume, the tubular member having an upper portion with a plurality of holes formed therethrough at an angle that is substantially normal to a longitudinal axis of the tubular member, each of the plurality of holes configured to allow introduction of a carrier gas into the interior volume.

2. The apparatus of claim 1, wherein the container comprises a precursor material.

3. The apparatus of claim 2, wherein a minimum distance between the perforated portion and a top surface of the precursor material contained in the container is about a quarter of an inch.

4. The apparatus of claim 2, wherein the precursor material comprises a fluid or solid precursor material.

5. The apparatus of claim 1, wherein the distal end of the tubular member includes a cap.

6. The apparatus of claim 1, wherein the distal end of the tubular member is restricted.

7. The apparatus of claim 1, wherein the distal end of the tubular member is open.

8. The apparatus of claim 1, further comprising at least one baffle extending substantially parallel to the tubular member in the interior volume.

9. The apparatus of claim 8, wherein the baffle is coupled to the bottom surface or the lid.

10. The apparatus of claim 1, further comprising a heater element.

11. A method for providing a vaporized precursor material to a processing chamber, comprising:
providing a container defining an interior volume containing a precursor material;
heating the precursor material to form a vapor;
flowing a carrier gas into the interior volume from a tubular member disposed in the interior volume, wherein the carrier gas is introduced from a perforated portion of the tubular member and the flow path is substantially normal relative to and parallel with the upper surface of the precursor material; and
flowing the carrier gas and vapor to an outlet.

12. The method of claim 11, wherein a minimum distance between the perforated portion and a top surface of the precursor material contained in the container is about a quarter of an inch.

13. The method of claim 11, wherein the precursor material comprises a fluid or solid precursor material.

14. The method of claim 11, wherein the distal end of the tubular member extends proximate to a bottom of the container.

15. The method of claim 11, wherein the distal end of the tubular member includes a cap.

16. The method of claim 11, wherein the distal end of the tubular member comprises an opening.

17. The method of claim 11 further comprising at least one baffle extending substantially parallel to the tubular member in the interior volume.

18. The method of claim 17, wherein the baffle extends either from a bottom or a top of the container.

19. The method of claim 11, further comprising heating the precursor material with a heater element.

20. The method of claim 11, wherein the perforated portion comprises a plurality of radial holes configured to generate a laminar flow of the carrier gas to evacuate the precursor material in a vaporized state to the outlet.

21. A canister apparatus, comprising:
an annular body having a outer diameter coupled to an outwardly extending flange portion having an outer diameter greater than the outer diameter of the annular body;
an interior volume defined by the annular body, the interior volume comprising an inside diameter transitioning to an inside diameter of the flange portion that is greater than the inside diameter of the interior volume; and
a plurality of arcuate shoulder regions coupled to and extending inwardly away from the inside diameter of the flange portion, each of the arcuate shoulder regions including a threaded opening adapted to receive a fastener.

22. The canister apparatus of claim 21 wherein a sidewall of the outer diameter of the annular body interface with an ambient atmosphere.

23. The canister apparatus of claim 21 wherein a sidewall of the interior volume interfaces with an atmosphere having a pressure lower than ambient atmosphere.

24. The canister apparatus of claim 21 wherein the arcuate shoulder regions further comprise a plurality of semicircular shoulders.

25. The canister apparatus of claim 24 wherein the semicircular shoulder further comprises at least one opening for receiving a fastener.
